(19) United States
(12) Patent Application Publication
(10) Pub. No.: US 2011/0070456 A1
(43) Pub. Date: Mar. 24, 2011

(54) Method for Producing an Organic Electronic Component, and Organic Electronic Component

(75) Inventors: Marc Philippens, Regensburg (DE); Richard Scheicher, Affing-Anwalting (DE); Andreas Lovich, Augsburg (DE); Ansgar Fischer, Koenigsbrunn (DE); Martin Muller, Untermeitingen (DE); Karsten Heuser, Erlangen (DE); Ralph Paetzold, Roth (DE)

(73) Assignee: OSRAM Opto Semiconductors GmbH, Regensburg (DE)

(21) Appl. No.: 12/922,833

(22) PCT Filed: Jun. 17, 2009
(86) PCT No.: PCT/DE2009/000860

§ 371 Date: Dec. 1, 2010

(30) Foreign Application Priority Data
Jul. 3, 2008 (DE) 102008031533.8

(51) Int. Cl. B32B 37/14; B32B 27/32

(52) U.S. Cl. 428/523; 156/278

(57) ABSTRACT

A method for producing an organic electronic component comprises, in particular, the following steps: A) producing at least one functional layer stack (10) with the following substeps: A1) providing a flexible first substrate (1), A2) applying at least one organic layer (2) in large-area fashion on the first substrate (1) by means of a coil coating plant (90), and A3) singulating the first substrate (1) with the at least one organic layer (2) into a plurality of functional layer stacks (10); B) providing a second substrate (5), which has a lower flexibility and a higher impermeability with respect to moisture and oxygen than the first substrate (1); and C) applying the at least one of the plurality of the functional layer stacks (10) with a surface (11) of the first substrate (1) remote from the organic layer (2) on the second substrate (5).

This patent application claims the priority of German patent application 10 2008 031 533.8, the disclosure content of which is hereby incorporated by reference.

A method for producing an organic electronic component, and an organic electronic component are specified.

To date there is no production method globally for large-area organic light-emitting diodes (OLEDs) for illumination purposes which achieves a cost-equivalent high production rate in comparison with displays. Known production methods have recourse to knowledge and techniques which originate from the production of LCD or OLED displays and which have been adapted and optimized for the production of large-area OLEDs. In this case, the production of large-area OLEDs in known methods is still based, for example, on providing the individual, large-area glass substrates with an indium tin oxide coating, onto which organic layers, comprising small organic molecules, and metal electrodes are deposited in large-volume, sealed coating installations (“in-line evaporators”). However, this technique is technically complex in terms of handling and must be improved with regard to many aspects in order to allow economic and cost-effective production of large-area OLEDs. One of the essential cost factors here is the handling of the glass substrates and of the masks which are required for forming active regions on the substrates.

No method has been disclosed hitherto, however, which is more efficient for producing large-area illumination devices with OLEDs and which differs with regard to the requirements of those for the production of OLED displays such that the production costs can be reduced in this way and OLED illumination devices become economic and hence competitive in comparison with other illumination devices. In particular, this can also apply to project businesses, in which high production flexibility may be of great importance owing to a large number of different organic electronic products in small numbers.

One object of at least one embodiment is to specify a method for producing an organic electronic component which has a functional layer stack. A further object of at least one embodiment is to specify an organic electronic component comprising a functional layer stack.

These objects are achieved by means of a method and an article comprising the features of the independent patent claims. Further features and advantageous embodiments and configurations of the method and of the article are characterized in the dependent claims and will furthermore become apparent from the following description and the figures.

A method for producing an organic electronic component comprises, in particular, the following substeps:
A) producing at least one functional layer stack with the following substeps:
   A1) providing a flexible first substrate,
   A2) applying at least one organic layer in large-area fashion on the first substrate by means of a coil coating plant, and
   A3) singulating the first substrate with the at least one organic layer into a plurality of functional layer stacks,
B) providing a second substrate, which has a lower flexibility and a higher impermeability with respect to moisture and oxygen than the first substrate, and
C) applying the at least one of the plurality of the functional layer stacks with a surface of the first substrate remote from the organic layer on the second substrate.

Thereby, the fact that one layer or one element is arranged or applied “on” or “above” another layer or another element can mean here and hereinafter that the one layer or the one element is arranged directly in direct mechanical and/or electrical contact on the other layer or the other element. Furthermore, it can also mean that the one layer or the one element is arranged indirectly on or above the other layer or the other element. In this case, further layers and/or elements can then be arranged between the one and the other layer and/or between the one and the other element.

The fact that one layer or one element is arranged “between” two other layers or elements can mean here and hereinafter that the one layer or the one element is arranged directly in direct mechanical and/or electrical contact or in indirect contact with one of the two other layers or elements and in direct mechanical and/or electrical contact or in indirect contact with the other of the two other layers or elements. In this case, in the case of indirect contact, further layers and/or elements can then be arranged between the one and at least one of the two other layers and/or between the one and at least one of the two other elements.

Here and hereinafter, “bottom” and “top” denote arrangements of layers and elements of the organic electronic component relative to the second substrate and/or to the at least one organic layer. In this case, a “bottom” layer can be arranged between the second substrate and a “top” layer, such that the bottom layer is applied on the second substrate and the top layer is applied on that side of the bottom layer which is remote from the second substrate. In particular, a bottom layer can be arranged for example between the second substrate and the organic layer and a top layer can be arranged on that side of the organic layer which is remote from the second substrate.

Here and hereinafter, “flexible” can denote, in particular, a substrate which is not rigid, but rather pliable, in particular reversibly pliable. In this case, however, in particular a substrate which is not pliable to the extent of infinitely small bending radii can also be designated as flexible, such that a flexible substrate within the meaning of the present description can for example also have a minimum bending radius, proceeding from which, in the case of smaller bending radii, an irreversible deformation of the substrate would occur.

Applying the at least one organic layer by means of the coil coating plant on the first substrate in a coil coating process, also referred to as so-called “web-based coating” or “roll-to-roll coating”, enables the first substrate to be coated in a cost-effective process capable of being conducted on a large scale. Coil coating methods of this type are known for example from newspaper printing or the coating of packets for potato chips with silicon oxide.

Materials suitable for being coated in coil coating plants typically have to have a certain and suitable flexibility. In this case, however, flexible materials suitable for coil coating plants may have a low impermeability with respect to moisture and oxygen, for example in the case of plastic materials. Since the first substrate is applied to the second substrate having a higher impermeability with respect to moisture and oxygen, the first substrate can be optimized with regard to its properties for the coil coating process without the need to take account of the impermeability of the first substrate with respect to moisture and oxygen in the choice of possible materials and forms of the first substrate. Furthermore, substrate materials suitable for coil coating plants, for example thin plastic and/or metal films, may have a low stability and robustness toward bending or other deformations, for example, and may therefore enable only limited handleability. By virtue of the combination of the first substrate with the second substrate, the second substrate can also serve as a supporting substrate for the organic electronic component.

Consequently, in the method described here, a high production rate can be made possible by the application of the at least one organic layer by means of the coil coating plant and at the same time a high impermeability with respect to oxygen and moisture can be made possible by the combination of the first with the second substrate.

In the coil coating plant, layers can be applied by means of wet-chemical or dry-chemical processes. In this case, wet- and dry-chemical methods, for instance printing methods and vacuum-based methods, can also be used in combined fashion and/or in a combined sequence. In particular, in the method described here, layers can be applied in structured or unstructured fashion for example without mask technology. Structured application of a layer comprising a specific material can be achieved for example by temporal variation of the amount of material that is to be applied.

The method described here is robust in the process engineering sense, that is to say is not very susceptible to faults, and comprises, for example with the application of the at least one organic layer by means of a coil coating plant, method steps which can make it possible to increase the production rate by virtue of a simple handling. As a result, the method described here enables a production method which is advanced and elegant in terms of process engineering and which, both with regard to the method steps and with regard to the machines and installations used, is less susceptible to faults and more economic in comparison with known methods and which enables a scalable, fast and cost-effective and/or cost-saving process chain.

In accordance with a further embodiment, an organic electronic component comprises, in particular,
at least one functional layer stack having at least one organic layer on a flexible first substrate, and
a second substrate, on which is arranged the at least one functional layer stack with a surface of the first substrate remote from the organic layer, wherein
the second substrate has a lower flexibility and a higher impermeability with respect to moisture and oxygen than the first substrate.

The organic electronic component can be producible cost-effectively and efficiently in particular by means of the method described above.

The features described below can apply equally to the method described above and to the optical electronic component.

The first substrate can be provided for example as a film composed of a plastic and/or a metal. In this case, the metal can comprise, in particular, high-grade steel, aluminum and/or copper or be composed of one or a plurality of metals. The plastic can comprise one or a plurality of polyolefins such as, for instance, high and low density polyethylene (PE) and polypropylene (PP). Furthermore, the plastic can also comprise polyvinyl chloride (PVC), polystyrene (PS), polyester and/or preferably polycarbonate (PC), polyethylene terephthalate (PET), polyether sulfone (PES) and/or polyethylene naphthalate (PEN).

In this case, the first substrate can be pliable and rollable and can be provided, in particular, as a film strip rolled up on a roll. In this case, the first substrate can also comprise a mixture, a layer sequence and/or a laminate composed of one or a plurality of plastics and/or of one or a plurality of metals. The first substrate can have a thickness of less than or equal to 1 mm, preferably less than or equal to 500 μm, and particularly preferably less than or equal to 250 μm. Furthermore, the first substrate can have a thickness of greater than or equal to 1 μm. By way of example, the first substrate can have a thickness of approximately 5 μm or a thickness of approximately 12 μm. The thicker the first substrate is made, the more stable it is with regard to the application of the at least one organic layer in the coil coating plant and also in the subsequent method steps. The thinner the first substrate, the more pliable and lighter the first substrate.

The first substrate, in particular a first substrate provided as a film in the above sense, does not have to be optimized with regard to its permeability or barrier function for moisture and/or oxygen. In this case, “permeable” can mean such a high permeability with respect to the diffusion of moisture and/or oxygen that the at least one organic layer and/or further layers or elements cannot be adequately protected against moisture and/or oxygen by the first substrate for permanent operation of the organic electronic component.

By way of example, the first substrate can be provided as a metal film or as a plastic film or as a layer sequence comprising a plastic film and a metal film. In this case, the for example one metal film can perform the function of a bottom electrode layer for the electronic component which can be produced in the method. Furthermore, the first substrate can comprise a pure metal or a metal alloy. Furthermore, the first substrate can also be provided with a coating in the form of an insulating or electrically conductive Bragg reflector and/or with a coating comprising a transparent buffer layer, for instance a plastic layer. Alternatively or additionally, layers of this type can also be applied by means of the coil coating plant.

The bottom electrode layer can be arranged between the first substrate and the at least one organic layer or be formed by the first substrate. Furthermore, the first substrate can comprise, as bottom electrode, a transparent conductive oxide (“TCO” for short) such as, for example, zinc oxide, tin oxide, cadmium oxide, titanium oxide, indium oxide or indium tin oxide (ITO). Alongside binary metal-oxygen compounds such as, for example, ZnO, SnO₂ or In₂O₃ ternary metal-oxygen compounds such as, for example, Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the group of TCOs. Furthermore, the TCOs do not necessarily correspond to a stoichiometric composition and can also be p- or n-doped.

The bottom electrode layer can furthermore comprise one or a plurality of metals, for instance aluminum, barium, indium, silver, gold, magnesium, calcium or lithium and compounds, combinations and alloys thereof. The bottom electrode layer can also comprise a combination comprising at least one TCO layer and at least one metal layer.

In particular, the bottom electrode layer can be embodied as transparent or reflective and comprise one or more of the materials mentioned above.

The first substrate can be transparent. In this case, the first substrate can be provided as light-scattering and/or as light-directing film. For this purpose, the first substrate can have for example a surface structure in the form of a roughening and/or microstructures such as, for instance, microprisms. Alternatively or additionally, the first substrate can comprise a plastic film comprising scattering particles and/or a wavelength conversion substance. As a result, the first substrate can be embodied as an optical waveguide, as a conversion film and/or as a scattering film which can direct or guide light for example in the finished organic electronic component through the first substrate, can convert electromagnetic radiation generated by the at least one organic layer at least partly into electromagnetic radiation having a different wavelength and/or can improve for example the coupling of light into the second substrate.

In this case, the scattering particles can be arranged on the surface of the first substrate or the plastic film or they can be enclosed in the plastic film embodied as matrix material.

In particular, the scattering particles can comprise for example a metal oxide, thus for instance titanium oxide or aluminum oxide such as, for instance, corundum, and/or glass particles and/or plastic particles which have a different refractive index than the matrix material. Furthermore, the scattering particles can have cavities and can be embodied in the form of hollow plastic spheres, for example. In this case, the scattering particles can have diameters or grain sizes of less than one micrometer up to an order of magnitude of 10 micrometers or else up to 100 micrometers.

The wavelength conversion substance can comprise one or a plurality of inorganic and/or organic materials, which can be selected for example from: granites of the rare earths and of the alkaline earth metals, nitrides, nitridosilicates, sions, sialons, aluminates, oxides, halophosphates, orthosilicates, sulfides, vanadates, chlorosilicates, perylenes, benzopyrenes, coumarins, rhodamines and azo dyes.

Thereby, the first substrate can be provided such that it already has a surface structure and/or scattering particles in method step A1. Alternatively or additionally, a surface structure and/or scattering particles can be applied, before or during method step A2, on the upper surface of the first substrate, said upper surface facing the organic layer to be applied in method step A2, or on the lower surface of the first substrate, said lower surface being remote from the organic layer to be applied in method step A2.

Furthermore, in method step A2, before the at least one organic layer is applied, a bottom electrode layer can be applied on the first substrate. In this case, the bottom electrode layer can comprise one or a plurality of metals, for instance aluminum, barium, indium, silver, gold, magnesium, calcium or lithium and compounds, combinations and alloys thereof. Alternatively or additionally, one or a plurality of TCO layers can be applied as bottom electrode layer in method step A2. The bottom electrode layer can also comprise a combination comprising at least one TCO layer and at least one metal layer. In this case, the bottom electrode layer can be applied for example by means of a vapor deposition method or by means of sputtering. Furthermore, a metal film can be laminated on the first substrate in method step A2 before the at least one organic layer is applied.

The bottom electrode layer can be applied or arranged continuously and in large-area fashion on the first substrate. Alternatively or additionally, the at least one organic layer can be applied continuously and in large-area fashion in method step A2. In this connection, “continuously and in large-area fashion” can mean for a layer that after application the layer has no partial regions that are separated from one another and electrically insulated from one another. Furthermore, the large-area and continuous layer can completely cover a main surface of the first substrate and thus be applied or arranged in area-covering fashion. Such continuous and large-area application of the at least one organic layer can be performed effectively and in a cost-saving manner precisely by means of the coil coating plant.

The at least one organic layer can be applied as part of an organic layer sequence in method step A2. In particular, it is possible to embody the organic electronic component with the at least one organic layer and/or the organic layer sequence as an organic light-emitting diode (OLED). For this purpose, the at least one organic layer or the organic layer sequence can comprise for example electron transport layers, electroluminescent layers, and/or hole transport layers, or be embodied as such. The at least one organic layer and/or the organic layer sequence can comprise organic polymers, organic oligomers, organic monomers, organic small, non-polymeric molecules (“small molecules”) or combinations thereof.

Depending on the material of the at least one organic layer, the latter can be applied on the first substrate by means of the coil coating plant for example by wet-chemical and/or vacuum-based methods such as, for instance, vapor deposition, spraying out, application by printing or application by doctor blade.

The at least one organic layer can be applied continuously and in large-area fashion. Furthermore, the at least one organic layer can also be applied in laterally structured fashion.

A top electrode layer can be applied on the at least one organic layer. In this case, the top electrode layer can comprise one or a plurality of the metals and/or TCOs mentioned further above in connection with the bottom electrode layer. In this case, the top electrode layer can be applied continuously and in large-area fashion after the application of, the at least one organic layer in method step A2 and before method step A3. In particular, the bottom electrode layer, the at least one organic layer and the top electrode layer can be applied by means of the coil coating plant in method step A2.

As an alternative thereto, the top electrode layer can also be applied after the singulation in method step A3 on the at least one organic layer of at least one of the functional layer stacks that can be produced by the singulation. In this case, the top electrode can be applied before or alternatively after method step C.

The first substrate and the first electrode can be embodied in transparent fashion, such that, for example, an organic electronic component embodied as an OLED, as a so-called “bottom emitter OLED”, can emit light generated in the at least one organic layer during operation through the bottom electrode layer and the first substrate and also through a second substrate embodied in transparent fashion. Alternatively or additionally, the top electrode layer can also be embodied in transparent fashion, such that the organic electronic component embodied as an OLED can also be embodied as a so-called “top emitter OLED”. In this case, the organic electronic component can be embodied simultaneously as bottom emitter and as top emitter, such that light generated in the organic layer can be emitted on both sides through the first and second substrates and through the top electrode layer. In particular, an OLED embodied as bottom and top emitter can be at least transparent.

The bottom electrode layer can be embodied for example as an anode, and the top electrode layer as a cathode. As an alternative thereto, the top electrode layer can also be embodied as an anode, and the bottom electrode layer as a cathode.

The first substrate with the at least one organic layer can be laterally singulated into a plurality of functional layer stacks in method step A3 by means of a mechanical, optical or thermal separation method or a combination thereof. A mechanical separation method can comprise for example mechanical cutting and/or die cutting. An optical separation method can comprise for example laser cutting. A thermal separation method can comprise for example hot wire cutting.

Furthermore, in method step A1 the first substrate can already be provided with continuous singulation regions, between which singulation lines such as, for instance, predetermined breaking or predetermined tearing lines and/or perforation lines are arranged, such that the at least one organic layer can be continuously applied to the first substrate with the continuous singulation regions in method step A2. In method step A3, the singulation regions with the at least one organic layer can then be simply detached from the first substrate along the singulation lines provided. Since method steps A1 and A2 before the singulation in method step A3 are independent of the subsequent form of the functional layer stacks, the first substrate with the at least one organic layer, after method step A2, can be singulated into functional layer stacks in any desired form in method step A3. Each of the plurality of the functional layer stacks then comprises, after singulation, the first substrate and thereon the at least one organic layer and—if present—a bottom and/or a top electrode layer and/or an organic layer sequence. After singulation, the functional layer stacks can have the same form or different forms in each case. The singulation can in this case also be carried out with regard to optimum utilization of the area of the first substrate with the at least one organic layer in order to minimize or even completely avoid possible rejects in respect of substrate area of the first substrate. By means of the singulation into functional layer stacks, the form of the subsequent active area of the organic electronic component, that is to say for example the luminous area in the case of an organic electronic component embodied as an OLED, can be chosen and individually altered and adapted to changed designs and layouts without complex structuring and mask processes.

The second substrate, provided in method step B, can preferably be hermetically impermeable with respect to oxygen and/or moisture. That can mean that the second substrate has a thickness which suffices to ensure that no oxygen and/or no moisture can diffuse through the second substrate. Furthermore, that can also mean that the second substrate comprises a material which generally or in conjunction with a sufficient is not permeable to oxygen and/or moisture. For this purpose, the second substrate can comprise metal and/or glass and/or ceramic. Furthermore, the second substrate can also comprise flexible, thin glass and/or a plastic with hermetically impermeable barrier layers, for instance high-density oxide and/or nitride layers.

The second substrate can furthermore also be embodied as UV protection and/or as protection with respect to mechanical impairments. Furthermore, the second substrate can also be embodied as a supporting substrate for the organic electronic component and can afford a stability with respect to bending and/or deformations not desired by the subsequent user.

The second substrate can be chosen independently of the method steps for producing the functional layer stacks with regard to its form and mechanical properties such as flexibility, for instance. By way of example, the second substrate can have a planar or a curved and bent main surface, on which the functional layer stack is applied in method step C, and can be rigid or flexible.

Furthermore, the second substrate can be surface-modified and provided with a light-scattering and/or light-directing surface. In this case, the light-scattering and/or light-refracting surface can have one or a plurality of features as described further above in connection with light-scattering and/or light-refracting properties of the first substrate. By way of example, the second substrate can have a surface which is remote from the first substrate and which has a surface structure as described above.

The at least one of the plurality of functional layer stacks that can be produced in method step A can be applied in method step C to form a mechanically fixed, that is to say positively locking and/or cohesive, connection by means of one or a plurality or a combination of a plurality of the following methods: thermal melting, for instance by means of a heating element, optical melting, for instance by means of a laser (“laser joining”), adhesive bonding, lamination, bonding and mechanical fixing, for instance clamping.

For the purpose of adhesive bonding and/or lamination, by way of example, between the second substrate and the functional layer stack, a connecting layer in the form of an electrically insulating or electrically conductive adhesive layer can be applied in unstructured fashion and in large-area fashion or in a manner structured into partial regions. The adhesive layer can thus cover the entire surface of the first substrate which faces the second substrate, or just parts thereof. Furthermore, as an alternative or in addition to the adhesive layer, a connecting layer comprising a thermally conductive paste, an optical gel such as, for instance, a refractive-index-matching gel, a refractive-index-matching adhesive or a combination thereof can also be applied between the second substrate and the functional layer stack in large-area fashion or in structured fashion. The connecting layer can therefore also comprise the adhesive layer and also comprise an electrically insulating or electrically conductive adhesive.

In method step B it is possible to provide the second substrate with at least one electrical contact element which enables the at least one functional layer stack to be electrically contact-connected to the second substrate. The electrical contact element can comprise for example a conductor track, an electrically conductive contact area and/or active or passive electronic components. The electrical contact element can be in electrical contact with a bottom or top electrode layer for example after method step C. Furthermore, the electrical contact element can be provided partly on the first substrate and partly on the second substrate before method step C, such that the electrical contact element is formed and completed by method step C.

Furthermore, it is possible to provide the second substrate with at least one electrical connection for making electrical contact with the organic electronic component. The electrical connection can comprise for example a conductor track, a bonding pad or an electrical contact area.

In particular, it is possible to provide the second substrate with a plurality of electrical contact elements and a plurality of electrical connections which are respectively provided for making electrical contact with a bottom electrode layer and a top electrode layer of a functional layer stack on the second substrate.

By means of the electrical connection or a plurality of electrical connections it is possible to provide a possibility for making electrical contact with the organic electronic component on the second substrate for a user, such that the latter can electrically connect the functional layer stack on the second substrate in a simple manner without said user having to attend to providing connection points on the functional layer.

The electrical contact element and/or the electrical connection can be provided for example by vapor deposition of metal, application of an electrically conductive paste and/or application of a wire connection (“wire bonding”). Furthermore, the electrical contact element and/or the electrical connection can be provided at least in part by application of an electrically conductive adhesive or a connecting layer as described above.

In a further method step D, after method step C, an encapsulation can be applied on the second substrate above the at least one functional layer stack, wherein the encapsulation completely covers the first substrate and hence the functional layer stack. That can mean that the encapsulation has a connecting area with the second substrate and the connecting area completely encompasses and surrounds the first substrate and hence the functional layer stack. The encapsulation can comprise for example a glass cover and/or a thin layer sequence comprising high-density vapor-deposited oxide and/or nitride layers.

The method described here thus affords the possibility of choosing the first substrate optimally for a coil coating process without taking account of possible barrier properties of the flexible first substrate with regard to oxygen and moisture. By virtue of the large-area application of the at least one organic layer, a mask-free process can be made possible, which makes possible a technically simple application installation. Furthermore, in the method described here, the method steps of applying the at least one organic layer and, if appropriate, the further layers such as electrode layer, for instance, are independent of the form of the organic electronic component and hence independent of the subsequent singulation step. As a result, at least almost the entire area made available by the first substrate can be utilized for applying the at least one organic layer, as a result of which the yield of the method described here can be maximized. After singulation, each functional layer stack can be tested beforehand with regard to its functionality, such that the probability of subsequent possible failure of the organic electronic component can be significantly reduced. Whereas in known production processes the form of an organic electronic component has to be chosen beforehand, is predetermined to the form of the individual substrate made available and has to be realized by means of an inline process through structured application of functional layers, the method described here is less cost-intensive, more flexible and faster than known production methods on account of the abovementioned features and advantages.

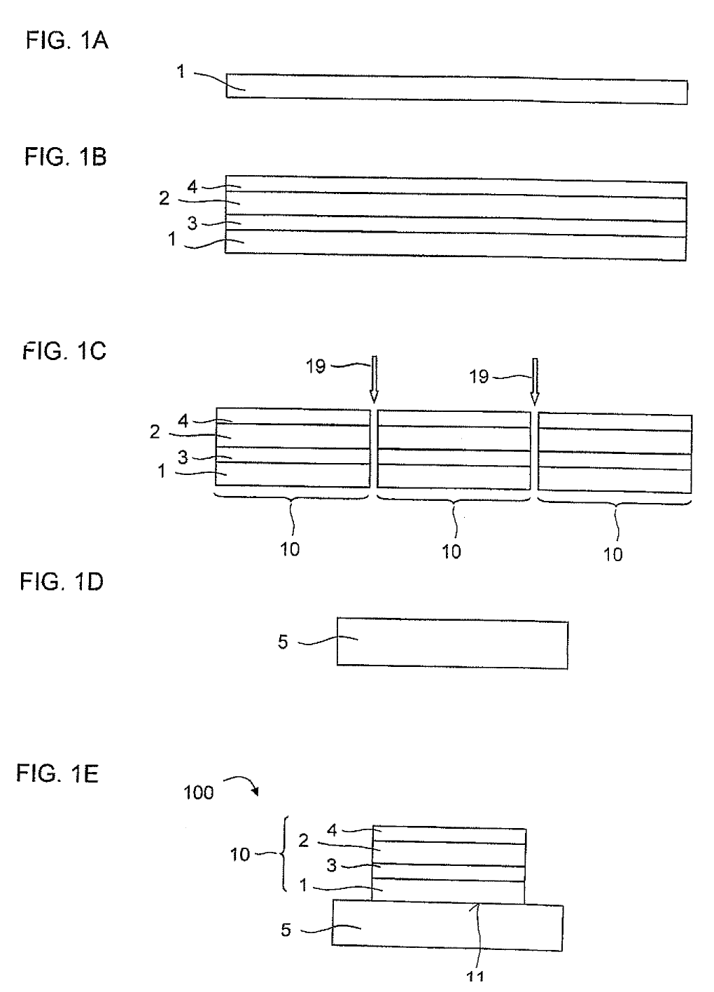

Further advantages and advantageous embodiments and developments of the invention will become apparent from the embodiments described below in conjunction with FIGS. 1A to 7I.

In the figures:

FIGS. 1A to 1E show schematic illustrations of a method for producing an organic electronic component in accordance with one exemplary embodiment,

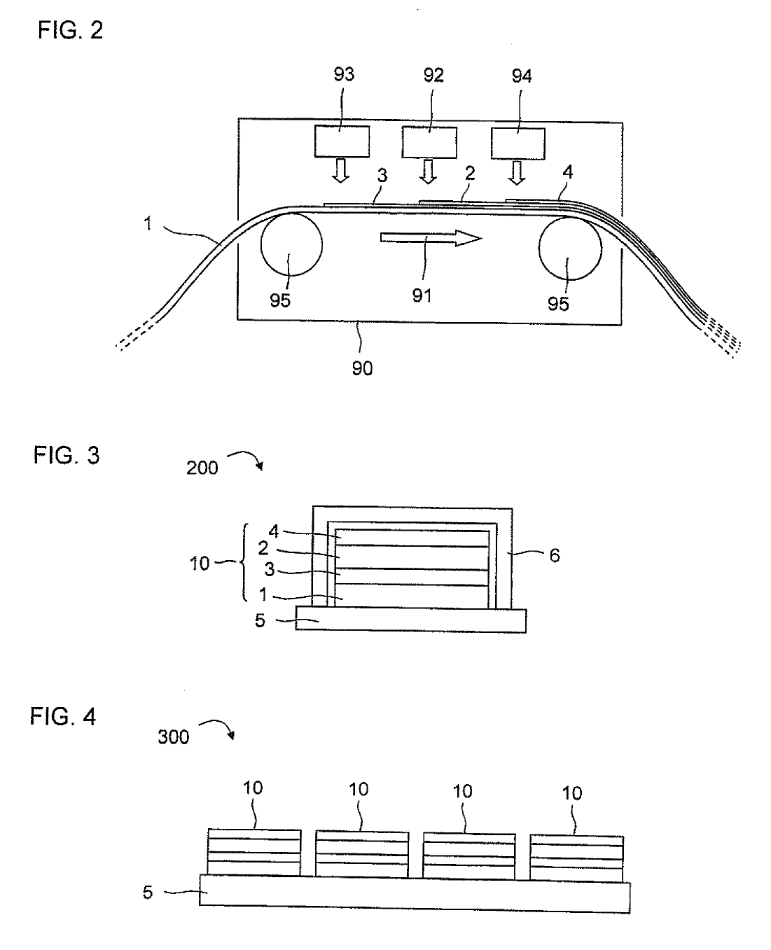

FIG. 2 shows a schematic illustration of a method step in accordance with a further exemplary embodiment,

FIGS. 3 to 6 show schematic illustrations of organic electronic components in accordance with further exemplary embodiments, and

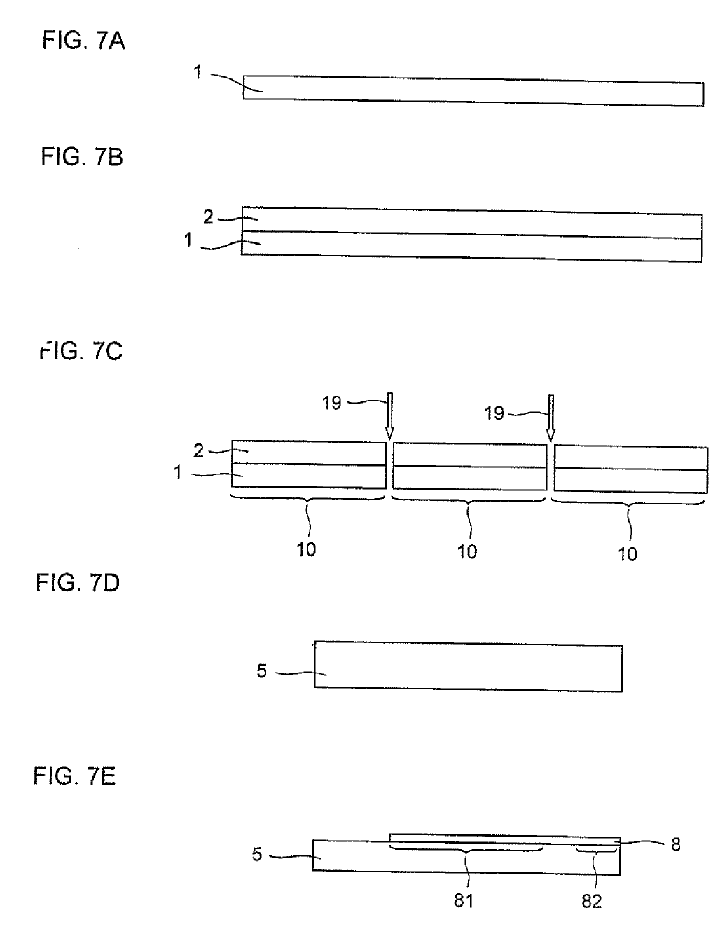

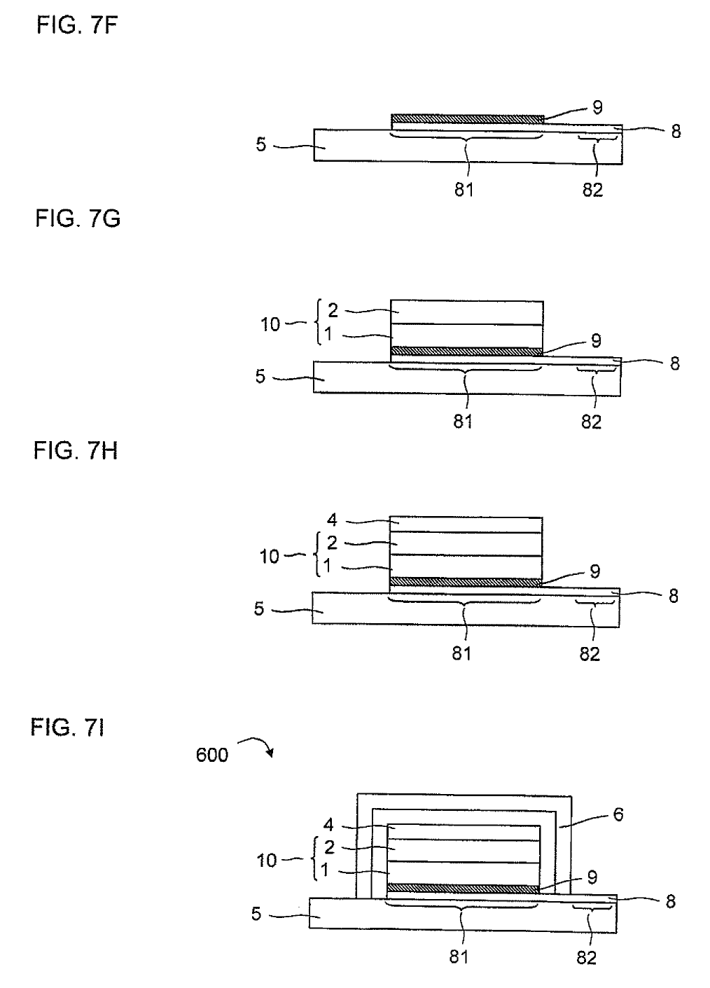

FIGS. 7A to 7I show schematic illustrations of a method for producing an organic electronic component in accordance with a further exemplary embodiment.

In the exemplary embodiments and figures, identical or identically acting constituent parts can in each case be provided with the same reference symbols. The elements illustrated and their size relationships among one another should not be regarded as true to scale, in principle; rather, individual elements such as, for example, layers, structural parts, components and regions may be illustrated with exaggerated thickness or size dimensions in order to enable better illustration and/or in order to afford a better understanding.

Methods and organic electronic components are shown below on the basis of the example of exemplary embodiments of methods for producing organic light-emitting diodes (OLEDs) and on the basis of the example of exemplary embodiments of OLEDs.

FIGS. 1A to 1E show one exemplary embodiment of a method for producing an organic electronic component 100.

In a first method step A, a functional layer stack 10 is produced. For this purpose, in a substep A1 of method step A in accordance with FIG. 1A, a flexible first substrate 1 is provided. The first substrate 1 is provided as a transparent, flexible film composed of a plastic. In this case, the first substrate 1, which is composed of polyethylene in the exemplary embodiment shown, is provided in the form of a film roll which can be processed further in a coil coating plant 90 in accordance with FIG. 2.

In a further substep A2 of method step A, in accordance with FIG. 1B, at least one organic layer 2 is applied on the first substrate 1 by means of the coil coating plant 90. In the exemplary embodiment shown, in accordance with FIG. 1B, furthermore, before the application of the at least one organic layer 2, a bottom electrode layer 3 is applied on the first substrate 1. A top electrode layer 4 is applied above the at least one organic layer 2. In the exemplary embodiment shown, a layer composed of indium tin oxide (ITO) is applied as bottom electrode layer 3 and an aluminum layer is applied as top electrode layer 4. The at least one organic layer 2 comprises an organic layer sequence comprising a hole transport layer, an electron transport layer and an active, electroluminescent region, in which electromagnetic radiation can be generated by recombination of holes and electrons during the operation of the organic electronic component 100. Further details concerning substep A2 and, in particular, concerning the coil coating plant 90 will be explained further below in connection with FIG. 2.

In a further substep A3 of method step A, in accordance with FIG. 1C, the first substrate 1 with the at least one organic layer 2 is singulated into a plurality of functional layer stacks 10, as is indicated by the arrows 19. In the exemplary embodiment shown, the singulation 19 is effected by mechanical cutting, wherein the forms of the functional layer stacks 10 can in this case be chosen individually and can be different from one another, for example. Alternatively, the singulation 19 can also be carried out by means of another separation method described in the general part. By way of example, a laser cutting separation method or a hot wire cutting separation method may also be advantageous particularly for complex forms of the functional layer stacks 10.

Each of the plurality of the functional layer stacks 10 can have a predetermined geometrical form, for example, by means of which decorative and/or informative impressions and effects can be brought about in the organic electronic component 100. Thus, the functional layer stacks 10 can for example also be singulated in the form of information-conveying pictograms, characters, letters and/or numbers.

In a further method step B in accordance with FIG. 1D, a second substrate 5 is provided, which has a lower flexibility than the first substrate 1 and also a higher impermeability with respect to moisture and oxygen. In the exemplary embodiment shown, the second substrate 5 is composed of transparent glass and has a thickness such that the second substrate 5 is hermetically impermeable with respect to moisture and oxygen.

In a further method step C in accordance with FIG. 1E, one of the plurality of the functional layer stacks 10 from method step A3 in accordance with FIG. 1C is applied with the surface 11 of the substrate 1 remote from the at least one organic layer 2 on the second substrate 5, as a result of which the organic electronic component 100 is formed. In this case, the functional layer stack 10 is laminated on the second substrate 5 by means of an adhesive layer (not shown). By way of example, the first substrate 1 can also be provided as a self-adhesive film with an adhesive layer on the surface 11 as early as in method step A1.

The organic electronic component 100 is embodied by means of the transparent first substrate 1, the bottom electrode layer 3 composed of ITO and the transparent second substrate 5 as a so-called bottom emitter OLED, that is to say as an OLED which can emit electromagnetic radiation generated in the at least one organic layer 2 through the second substrate 5.

FIG. 2 shows an exemplary embodiment of method step A2 in accordance with the preceding exemplary embodiment. For this purpose, a coil coating plant 90 is provided, which is indicated purely schematically in FIG. 2.

The first substrate 1, which, as described above, is provided as a plastic film on a roll (not shown), is transported by means of a transport mechanism 95 through the coil coating plant 90 along a processing direction 91, and coated. The coated first substrate 1 with the at least one organic layer 2 and the bottom and top electrode layers 3, 4 in accordance with the exemplary embodiment shown can, after the application of the layers, once again be rolled up on a roll (not shown) and be provided in this form for the further method steps. In this case, the rolls for supplying the first substrate 1 and for taking up the coated first substrate 1 and also the coil coating plant 90 are arranged in a vacuum or in a protective gas atmosphere in order to avoid degeneration of the at least one organic layer 2 and of the bottom and top electrode layers 3, 4 owing to oxygen and moisture.

In the coil coating plant 90, coating elements 93, 92 and 94 are arranged successively, which, in the exemplary embodiment shown, by means of thermal evaporation, apply the bottom electrode layer 3, thereabove the at least one organic layer 2 in the form of the above-described layer sequence and thereabove the top electrode layer 4 on the first substrate 1. In this case, the application of the bottom electrode layer 3, the at least one organic layer 2 and the top electrode layer 4 is effected continuously without interruption, such that a high production rate and hence a high economic viability can be achieved. As an alternative to thermal evaporation, the bottom electrode layer 3 can also be applied by sputtering, for example. The at least one organic layer can also be applied by means of a wet-chemical method, for example.

FIG. 3 shows a further exemplary embodiment of an organic electronic component 200 which can be produced by means of a method in accordance with FIGS. 1A to 1E and in which, in a further method step D, an encapsulation 6 is applied above the functional layer stack 10.

In the exemplary embodiment shown, the encapsulation 6 comprises a glass cover applied on the second substrate 5. In this case, the glass cover is fixed on the second substrate 5 by means of an adhesive layer (not shown) and has an interface with the second substrate 5, said interface being arranged in a manner extending around the functional layer stack 10. By means of the hermetically impermeable second substrate 5 and the encapsulation 6, it is possible to achieve an effective and hermetically impermeable protection of the functional layer stack 10 independently of the impermeability properties of the first substrate 1.

As an alternative or in addition to the glass cover, the encapsulation 6 can also comprise a thin-film encapsulation as described in the general part.

FIG. 4 shows a further exemplary embodiment of an organic electronic component 300, in which, in method step C, a plurality of functional layer stacks 10 are applied alongside one another on the second substrate 5. As an alternative thereto or in addition, functional layer stacks 10 can also be applied one above another. In this case, the individual functional layer stacks 10 can for example each have a different form and be put into operation independently of one another in the completed organic electronic component 300. Furthermore, the functional layer stacks 10 can be produced in different method steps A and comprise different materials, for instance.

By virtue of the plurality of functional layer stacks 10, the organic electronic component 300 embodied as an OLED can for example give different color impressions in different operating states and/or have different luminous areas and thereby enable a variable luminous impression and/or variable information reproduction.

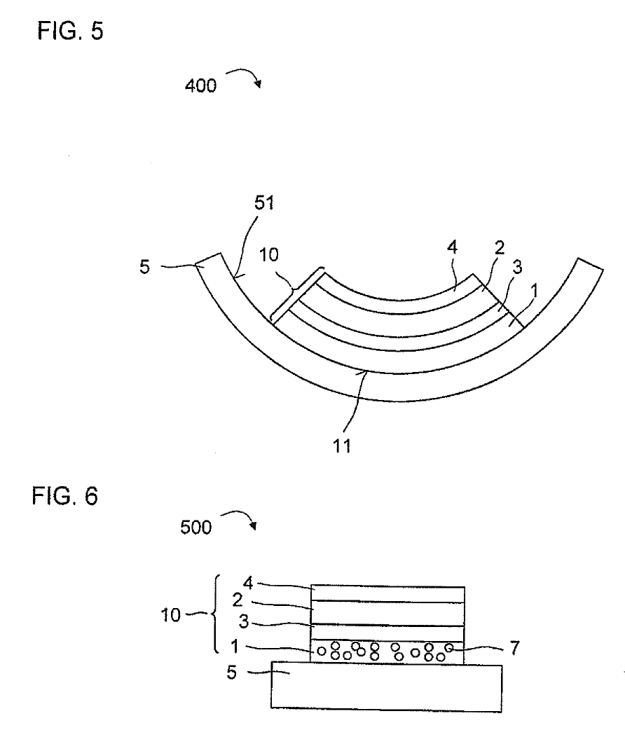

FIG. 5 shows a further exemplary embodiment of an organic electronic component 400, which has a bent second substrate 5. The functional layer stack 10 is thus arranged on a bent and curved main surface of the second substrate 5. On account of the fact that the first substrate 1 is suitable for a coil coating process in accordance with method step A2, the form of the functional layer stack 10 can also be adapted to surfaces having a high degree of curvature.

Alternatively or additionally, the second substrate 5 can be flexible, wherein the functional layer stack 10, by virtue of the higher flexibility of the first substrate 1 in comparison with the second substrate 5, is not impaired in terms of its functionality by changes in the curvature of the second substrate 5.

FIG. 6 shows a further exemplary embodiment of an organic electronic component 500, which has a first substrate 1 comprising scattering particles 7. In this case, the first substrate 1 is provided as a film comprising a plastic as matrix material, into which the scattering particles, for example glass particles, are embedded. The first substrate 1 can increase the coupling of light from the first substrate 1 into the second substrate 5 during the operation of the organic electronic component 500 embodied as an OLED.

As an alternative or in addition to the above-described features of the first substrate 1 in the exemplary embodiment shown, the first substrate 1 can also have further light-scattering or light-directing features as described in the general part. As an alternative or in addition to the scattering particles 7, the first substrate 1 can also comprise a wavelength conversion substance, for example.

FIGS. 7A to 7I show a further exemplary embodiment of a method for producing an organic electronic component 600.

In a first method step A in accordance with FIGS. 7A to 7C, a plurality of functional layer stacks 10 are produced. For this purpose, in a first substep A1 of method step A, a flexible first substrate 1 is provided, which is embodied as a metal film. In this case, the first substrate 1 is provided in the form of a high-grade steel film suitable for a coil coating process, which film, subsequently in the organic electronic component 600, can act simultaneously as a bottom electrode layer. As an alternative thereto, by way of example, a laminate comprising a plastic film and a metal film or a metal-coated plastic film can also be provided as the first substrate.

In a second substep A2 of method step A, in accordance with FIG. 7B, a first organic layer 2 is applied in large-area fashion and continuously on the first substrate 1 by means of a coil coating plant. In this case, the coil coating plant can have features as described in conjunction with FIG. 2 and as described in the general part. The at least one organic layer 2 comprises an organic layer sequence comprising at least one hole transport layer, at least one electroluminescent layer and at least one electron transport layer, which are applied in a wet-chemical method.

In a further substep A3 of method step A in accordance with FIG. 7C, the first substrate 1 coated with the at least one organic layer 2 is singulated into functional layer stacks 10, as is indicated by the arrows 19. The singulation 19 is effected by die cutting in the present exemplary embodiment.

A further method step B in accordance with FIGS. 7D and 7E involves providing a second substrate 5 composed of glass with a conductor track 8. For this purpose, in a first substep in accordance with FIG. 7D, the second substrate 5 is provided. In a second substep in accordance with FIG. 7E, a conductor track 8 is applied on a main surface of the second substrate 5 by vapor deposition of a metal.

The conductor track 8 has an electrical contact element 81 for subsequently making electrical contact with one of the functional layer stacks 10 produced in method step A. In this case, the electrical contact element 81 is simultaneously embodied as a mounting area for a functional layer stack 10.

The conductor track 8 furthermore has an electrical connection arranged alongside the mounting region formed by the electrical contact element 81. The organic electronic component 600 can be electrically contact-connected via the electrical connection 82 for example by bonding or by connection of a suitable plug connector for subsequent start-up by a user, without the user having to make contact directly with the functional layer stack 10 itself.

In addition to the conductor track 8 shown, still further conductor tracks, for example for making electrical contact with a top electrode layer 4, can be applied on the second substrate 5. Furthermore, in addition to the conductor tracks, electronic active and/or passive components can also be applied on the second substrate 5.

In a further method step C in accordance with FIGS. 7F to 7H, a functional layer stack 10 produced in method step A is applied on the second substrate 10. For this purpose, in a substep of method step C, an electrical connecting layer 9 is applied on the electrical contact element 81 of the conductor track 8. In the exemplary embodiment shown, the electrical connecting layer comprises an electrically conductive adhesive. As an alternative thereto, the connecting layer can also comprise a solder having a low melting point, for example.

In accordance with FIG. 7G, in a further substep of method step C, a functional layer stack 10 produced in method step A is applied to the connecting layer 9 on the electrical contact element 91 of the conductor track 8. An electrical contact between the at least one organic layer 2 and the electrical connection 82 can thus be effected via the conductor track 8, the connecting layer 9 and the first substrate 1, acting as a bottom electrode layer.

In a further method step in accordance with FIG. 7H, a transparent top electrode layer 4 comprising a transparent metal layer is applied on the at least one organic layer 2 of the functional layer stack 10. As an alternative or in addition thereto, the top electrode layer 4 can also comprise one or a plurality of TCO layers. In this case, the top electrode layer 4 can also be applied in such a way that it is possible to provide an electrical connection via a further conductor track (not shown).

In a further method step D in accordance with FIG. 7I, a transparent encapsulation 6 in the form of a multilayered thin-film encapsulation is applied above the functional layer stack 10, said encapsulation completely covering the functional layer stack 10 and forming together with the second substrate 5 a hermetically impermeable encapsulation for the functional layer stack 10.

The organic electronic component 600 produced in this way can generate light during operation in the at least one organic layer 2, and said light can be emitted through the transparent top electrode layer 4 and the encapsulation 6 in a direction facing away from the second substrate 5, such that the organic electronic component is embodied as a top emitter OLED in the exemplary embodiment shown.

The invention is not restricted to the exemplary embodiments by the description on the basis of said exemplary embodiments. Rather, the invention encompasses any novel feature and also any combination of features, which in particular includes any combination of features in the patent claims, even if this feature or this combination itself is not explicitly specified in the patent claims or exemplary embodiments.

1. A method for producing an organic electronic component comprising the following steps:
A) producing at least one functional layer stack with the following substeps:
A1) providing a flexible first substrate,
A2) applying at least one organic layer in large-area fashion on the first substrate by means of a coil coating plant, and
A3) singulating the first substrate with the at least one organic layer into a plurality of functional layer stacks;
B) providing a second substrate, which has a lower flexibility and a higher impermeability with respect to moisture and oxygen than the first substrate; and
C) applying the at least one of the plurality of the functional layer stacks with a surface of the first substrate remote from the organic layer on the second substrate.

2. The method as claimed in claim 1, wherein the first substrate comprises a film composed of a plastic and/or a metal.

3. The method as claimed in claim 1, wherein the first substrate is permeable to moisture and oxygen.

4. The method as claimed in claim 1, wherein the at least one organic layer is applied continuously and in large-area fashion on the first substrate.

5. The method as claimed in claim 1, wherein in method step A3 the first substrate is singulated by means of a mechanical, optical or thermal separation method or a combination thereof.

6. The method as claimed in claim 1, wherein before the singulation in method step A3 a top electrode layer is applied on the at least one organic layer.

7. The method as claimed in claim 1, wherein after the singulation in method step A3 a top electrode layer is applied on the at least one organic layer.

8. The method as claimed in claim 1, wherein the second substrate is hermetically impermeable with respect to oxygen and/or moisture.

9. The method as claimed in claim 1, wherein method step B involves providing the second substrate with at least one electrical contact element for electrically contact-connecting the at least one functional layer stack to the second substrate.

10. The method as claimed in claim 1, wherein method step C involves applying the at least one functional layer stack by means of a connecting layer comprising a thermally conductive paste, a refractive-index-matched adhesive, a refractive-index-matched gel, an electrically conductive adhesive or a combination thereof on the second substrate.

11. The method as claimed in claim 1, comprising the following additional step:
D) applying an encapsulation on the second substrate above the at least one functional layer stack, wherein the encapsulation completely covers the functional layer stack.

12. An organic electronic component, comprising:
at least one functional layer stack having at least one organic layer on a flexible first substrate; and
a second substrate, on which is arranged the at least one functional layer stack with a surface of the first substrate remote from the organic layer,
wherein the second substrate has a lower flexibility and a higher impermeability with respect to moisture and oxygen then the first substrate.

13. The component as claimed in claim 12, wherein a connecting layer comprising a thermally conductive paste, a refractive-index-matching gel, a refractive-index-matching adhesive, an electrically conductive adhesive or a combination thereof is arranged between the at least one functional layer stack and the second substrate.

14. The component as claimed in claim 12, wherein the second substrate has at least one electrical contact element for making electrical contact with the at least one functional layer stack.

15. The component as claimed in claim 12, wherein an encapsulation is arranged on the second substrate above the at least one functional layer stack, wherein the encapsulation completely covers the functional layer stack.
